(19) United States
(12) Patent Application Publication
(10) Pub. No.: US 2010/0193849 A1
(43) Pub. Date: Aug. 5, 2010

(54) SEMICONDUCTOR MEMORY DEVICE INCLUDING FERROELECTRIC FILM AND A METHOD FOR FABRICATING THE SAME

(75) Inventors: Jun NISHIMURA, Kanagawa-ken (JP); Yoshinori KUMURA, Albany, CA (US); Hiroyuki KANAYA, Kanagawa-ken (JP); Tohru OZAKI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/689,164

(22) Filed: Jan. 18, 2010

(30) Foreign Application Priority Data
Feb. 5, 2009 (JP) 2009-025390

(51) Int. Cl. H01L 27/108; H01L 21/8242

(52) U.S. Cl. 257/295; 438/3; 257/E27.084; 257/E21.647

(57) ABSTRACT

According to one embodiment, a semiconductor memory device having a ferroelectric film, includes a semiconductor substrate, a field effect transistor formed on the semiconductor substrate, an inter-layer insulating film formed on the field effect transistor and the semiconductor substrate, a plug constituted with a single-crystalline structure, the plug being formed in the inter-layer insulating film and being connected with a source or a drain of the field effect transistor, a lower electrode constituted with a single-crystalline structure formed on the plug, a ferroelectric film formed on the lower electrode an upper electrode formed on the ferroelectric film.

### CROSS REFERENCE TO RELATED APPLICATION

This application is based upon and claims the benefit of priority from prior Japanese Patent Application No. 2009-025390, filed on Feb. 5, 2009, the entire contents of which are incorporated herein by reference.

### TECHNICAL FIELD

Exemplary embodiments described herein relate to a semiconductor memory device and a method for fabricating the semiconductor memory device which include a ferroelectric film.

### BACKGROUND

A ferroelectric random access memory (FeRAM) using ferroelectrics has been actively developed from view point of higher speed writing, lower power consumption, higher rewriting number and the like. Miniaturization of the FeRAM has been also advanced accompanying with recent miniaturization of a semiconductor device.

As the FeRAM has a structure with thin-film ferroelectric capacitor, a contact area of the capacitor becomes small accompanying with the miniaturization. Therefore, a problem is generated in the FeRAM. Here, the contact area means an area contacted with a ferroelectric thin-film formed between a capacitor electrode and an electrode.

Reducing the contact area to be lower than a prescribed area rapidly decreases a signal amount between the ferroelectric thin-film and the electrode. The decrease of the signal amount produces difficulty for promoting the miniaturization.

A lower electrode is formed as a bell shape in changing with a conventional stack structure, so that a structure having a ferroelectric thin-film formed on an upper portion and a side portion of the lower electrode is proposed, for example, in JP-A 2005-251985 (KOKAI). The contact area between the ferroelectric thin-film and the electrode is increased by using the structure so as to increase the signal amount in the FeRAM.

It has been well-known that characteristics of a ferroelectric thin-film capacitor is closely related to a material and crystalline structure of the ferroelectric thin-film. The ferroelectric thin-film cannot act as ferroelectric without crystallization in different with a transistor in a silicon substrate. Accordingly, selecting the material is important.

However, a problem that the ferroelectric thin-film on the side portion of the lower electrode is not crystallized or a composition ratio of the ferroelectric thin-film is changed with the crystallization or the like is generated, when the lower electrode is not formed as the bell shape.

### SUMMARY

An aspect of the present disclosure relates to a semiconductor memory device having a ferroelectric film, including a semiconductor substrate, a field effect transistor formed on the semiconductor substrate, an inter-layer insulating film formed on the field effect transistor and the semiconductor substrate, a plug constituted with a single-crystalline structure, the plug being formed in the inter-layer insulating film and being connected with a source or a drain of the field effect transistor, a lower electrode constituted with a single-crystalline structure formed on the plug, a ferroelectric film formed on the lower electrode an upper electrode formed on the ferroelectric film.

Another aspect of the present disclosure relates to a method for fabricating a semiconductor memory device having a ferroelectric film, including, forming a field effect transistor on a semiconductor substrate, forming an inter-layer insulating film on the field effect transistor and the semiconductor substrate, forming a plug constituted with a single-crystalline structure in the inter-layer insulating film, the plug being connected with a source or a drain of the field effect transistor, forming an lower electrode constituted with a single-crystalline structure on the plug, forming a ferroelectric film on the lower electrode, and forming an upper electrode on the ferroelectric film.

### DESCRIPTION OF THE DRAWINGS

FIG. 1 is a cross-sectional diagram showing a semiconductor memory device according to an embodiment of the present invention;

FIG. 2 is a cross-sectional diagram showing a method for fabricating the semiconductor memory device according to the embodiment of the present invention;

FIG. 3 is a cross-sectional diagram showing the method for fabricating the semiconductor memory device according to the embodiment of the present invention;

FIG. 4 is a cross-sectional diagram showing the method for fabricating the semiconductor memory device according to the embodiment of the present invention;

FIG. 5 is a schematic view showing a crystalline structure of each layer in the semiconductor memory device according to the embodiment of the present invention;

FIG. 6 is a cross-sectional diagram showing the method for fabricating the semiconductor memory device according to the embodiment of the present invention;

FIG. 7 is a cross-sectional diagram showing the method for fabricating the semiconductor memory device according to the embodiment of the present invention;

FIG. 8 is a cross-sectional diagram showing the method for fabricating the semiconductor memory device according to the embodiment of the present invention;

FIG. 9 is a cross-sectional diagram showing the method for fabricating the semiconductor memory device according to the embodiment of the present invention;

FIG. 10 is a cross-sectional diagram showing the method for fabricating the semiconductor memory device according to the embodiment of the present invention;

FIG. 11 is a cross-sectional diagram showing the method for fabricating the semiconductor memory device according to the embodiment of the present invention;

FIG. 12 is a cross-sectional diagram showing the method for fabricating the semiconductor memory device according to the embodiment of the present invention;

### DETAILED DESCRIPTION

Embodiments of the present invention will be described below in detail with reference to the drawing mentioned above.

### Embodiment

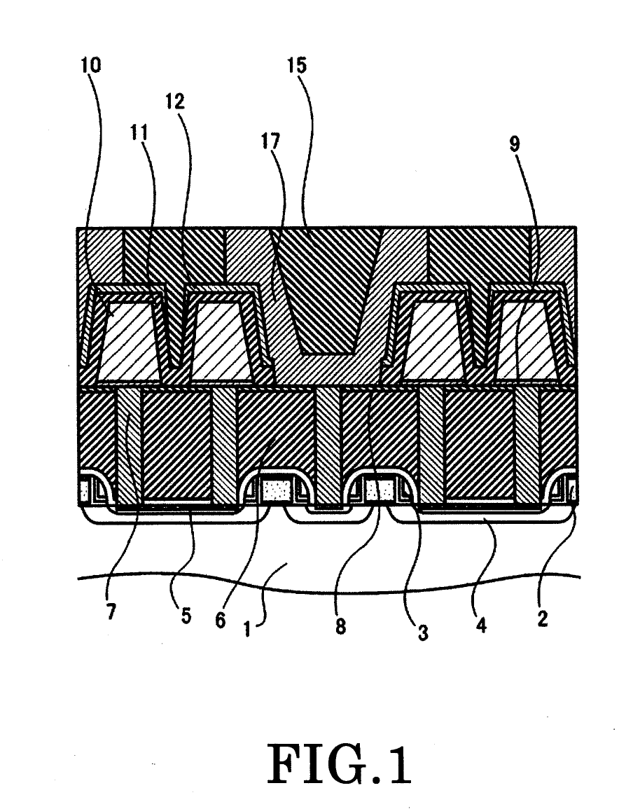

FIG. 1 is a cross-sectional diagram showing a semiconductor memory device according to an embodiment of the present invention. As shown in FIG. 1, a gate electrode 2 is formed above a silicon substrate 1 in a semiconductor memory device. A gate side-wall insulator 3 is formed on a side-wall of the gate electrode 2. The gate electrode 2 can be formed by a poly-crystalline silicon film, a tungsten-silicon compound film (WSi), a poly-side structure which is constituted with a stack structure having the poly-crystalline silicon film and the WSi film or the like, for example. Further, the gate side-wall insulator 3 is formed, for example, a silicon nitride film or the like.

Impurity diffusion regions 4 having an n-type or a p-type are configured in self-align to the gate electrode 2 and the gate side-wall insulator 3. A metal oxide semiconductor (MOS) transistor is constituted with the gate electrode 2 above the silicon substrate 1, the gate side-wall insulator 3, the impurity diffusion regions 4 and the like. Further, a silicide layer 5 is formed on each impurity diffusion region 4.

An inter-layer insulating film 6 is formed on the MOS transistor and the silicide layer 5. A surface of the inter-layer insulating film 6 is flattened. The inter-layer insulating film 6 is constituted with boron phosphorous silicon glass (BPSG), for example. A contact plug 7 is formed in the inter-layer insulating film 6. The contact plug 7 electrically connects between the silicide layer 5 in the impurity diffusion region 4 and a ferroelectric capacitor mentioned later.

In this embodiment, the contact plug 7 is formed with a single-crystalline silicon film. A hydrogen barrier film 8 constituted with an aluminum-oxide (Al₂O₃) film, a silicon nitride (SiN) film or the like, for example, may be formed on the inter-layer insulating film 6. The hydrogen barrier film 8 has an effect of suppressing diffusion of lead (Pb) element or the like from the ferroelectric film formed as an upper layer to the inter-layer insulating film 6 or the like. Accordingly, the hydrogen barrier film 8 may be not formed when a film without Pb element is used as the ferroelectric film.

A silicon film 9 is formed at a prescribed position on the contact plug 7 and the inter-layer insulating film 6. The silicon film 9 formed on the contact plug 7 can be a single-crystalline silicon film by forming the contact plug 7 as the single-crystalline silicon film. In other word, the silicon film 9 can be formed by epitaxially growing the single-crystalline silicon of the contact plug 7.

A lower electrode 10 having a bell shape or a columnar type is formed on the silicon film 9. The bell shape has a taper angle below 90 degrees to be formed as decreasing a diameter thereof accompanying with a direction to an upper portion. The lower electrode 10 is constituted with a single-crystalline metal film having a perovskite structure, for example, SrRuO₃ or the like.

Here, the lower electrode 10 may be formed as the columnar type or the bell shape, as a contact area between the ferroelectric film 11 at the upper portion and the lower electrode 10 can be increased. The lower electrode 10 is not necessary to be constituted with single material, a stack structure may be used. The silicon film and the lower electrode 10 may be collectively called as a lower electrode.

A ferroelectric film 11 is formed to cover the lower electrode 10. Especially, the ferroelectric film 11 on a sidewall of the bell-shaped electrode is desirable to be lattice-matched with the lower electrode 10 by forming the lower electrode 10 with the bell shape as the single-crystalline metal film. Therefore, characteristics of the ferroelectric capacitor can be improved as mentioned below.

As capacitor characteristics of the ferroelectric capacitor such as leakage current characteristics, C-V characteristics, polarization characteristics, imprint characteristics, fatigue characteristics, retention characteristics or the like is closely related to material and crystalline structure of the electrode, a selection of the material is important. Here, polarization characteristics means polarization amount, saturation characteristic or the like, imprint characteristics means a phenomenon which polarization easily points one direction in a case of retaining polarization by the one direction, fatigue characteristics means deterioration behavior of the polarization amount by polarization reverse and retention characteristics means deterioration behavior of the polarization amount retained.

A material having a crystal structure based on the perovskite structure, for example, Pb(Zrₓ, Ti₁₋ₓ)O₃ (PZT), Bi₄Ti₃O₁₂ (BIT), SrBi₂Ta₂O₉ (SBT) and including residual polarization is used as the ferroelectric film. In this case, Ir, IrO₂, Pt or the like is used as the lower electrode. Crystallinity of the ferroelectric film 11 is known to be influenced with crystallinity of the lower electrode 10 being as a lower layer. The crystallinity of the ferroelectric film 11 is considered to be improved by crystallizing the lower electrode 10.

An upper electrode 12 is formed on the ferroelectric film 11, for example, Pt, Ir, IrO₂, Ru, RuO₂, SrRuO₃ (SRO), LaNiO₃ (LNO), (La, Sr)CoO₃ (LSCO) or the like which is conductive compound oxide or the like represented by noble metal, noble metal oxide or perovskite structure. The lower electrode 10 is not necessary to be constituted with a single material, but a stack structure may be used.

In this embodiment, the perovskite type single-crystalline metal film as the same crystal structure as the ferroelectric film 11 is used as the lower electrode 10. The ferroelectric film 11 is lattice-matched with a crystal texture of the lower electrode 10 in the crystallization process using the perovskite-type single-crystalline metal film as the lower electrode 10. The crystallinity of the ferroelectric film 11 is improved. The ferroelectric capacitor is constituted with the lower electrode 10, the thin ferroelectric film 11 and the upper electrode as mentioned above.

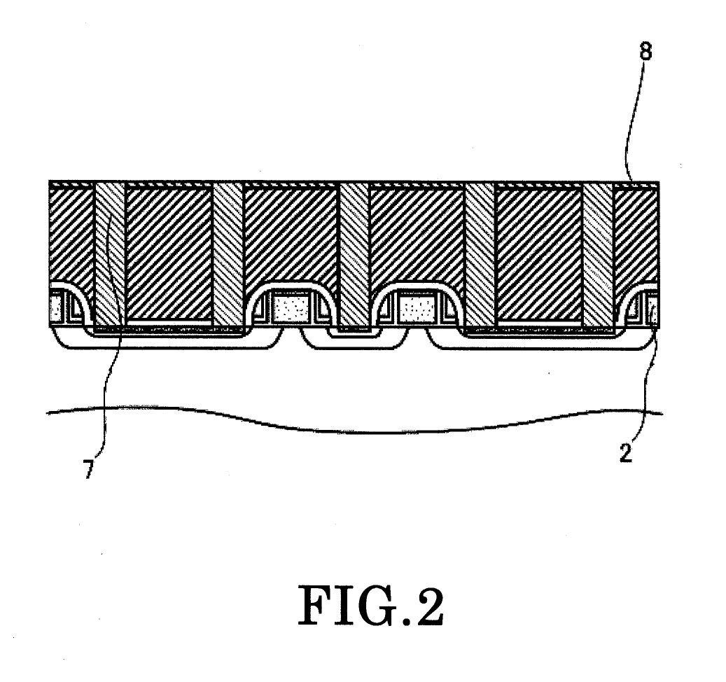

Successively, a method for fabricating the semiconductor memory device is explained according to the embodiment of the present invention. FIGS. 2-13 are cross-sectional and plane diagrams showing an embodiment of fabrication processes of the semiconductor memory device. The method for fabricating the semiconductor memory device is explained in an order using FIGS. 2-13 as a reference. Further, In this embodiment, PZT is used as the ferroelectric film 12.

As shown in FIG. 2, a prescribed pattern is formed on a surface of the semiconductor substrate 1, for example, a silicon substrate or the like, by shallow trench isolation (STI) or the like. Subsequently, the MOS transistor is formed on a region surrounded by an isolation insulator on the semiconductor substrate 1 as described below.

For example, a gate insulator, for example, a silicon oxide film or the like, an n-type poly-crystalline silicon film doped with arsenic and a gate cap film, for example, a nitride silicon film or the like are stacked to be formed in a order on the semiconductor substrate 1. Subsequently, the gate insulator, the n-type poly crystalline silicon film and the nitride silicon film are etched to be formed the gate electrode 2 constituted with the stack layer having a prescribed feature by conventional lithography and reactive ion etching (RIE). Further, conductive impurities are ion-implanted into the semiconductor substrate 1 using the gate electrode 2 as a mask. Subsequently, the semiconductor substrate 1 is thermally treated. Consequently, a source 4 and a drain 4 with the prescribed impurity are formed on both side surfaces of gate electrode 2 in the semiconductor substrate 1 along a line width direction.

Subsequently, an insulator, for example, a silicon nitride film or the like is formed on the semiconductor substrate 1. The insulator on the surface of the semiconductor substrate 1 is removed by anisotropic etching using RIE. As a result, the insulator only both side surfaces of gate electrode 2 is leaved in the semiconductor substrate 1 along a line width direction to form the gate side-wall insulator 3. Accordingly, the MOS transistor is formed in the prescribed region surrounded by the isolation insulator.

a metal film, for example, nickel (Ni), tantalum (Ta) or the like is deposited on the gate electrode 2 and the impurity diffusion region 4, the semiconductor substrate 1 is subsequently performed with heat treatment to form the silicide layer 5. After that, BPSG film as the inter-layer insulating film 6 is entirely formed over the silicon substrate 1, for example, by using chemical vapor deposition (CVD) or the like. The upper surface of the silicon substrate 1 is flattened by chemical mechanical polishing (CMP). Furthermore, an aluminum oxide (Al₂O₃) film as the hydrogen barrier film 8 is formed on the BPSG film 6 by using atomic layer deposition (ALD), sputtering, CVD or the like.

After forming the Al₂O₃ film 8, the Al₂O₃ film 8 and the BPSG film 6 are anisotropically etched in an order for example, by reactive ion etching (RIE) or the like. A contact hole connected to one of the source 4 and the drain 4 in the MOS transistor is formed. The single crystalline silicon plug 7 as the contact plug 7 is formed in the contact hole by using epitaxial growth or the like.

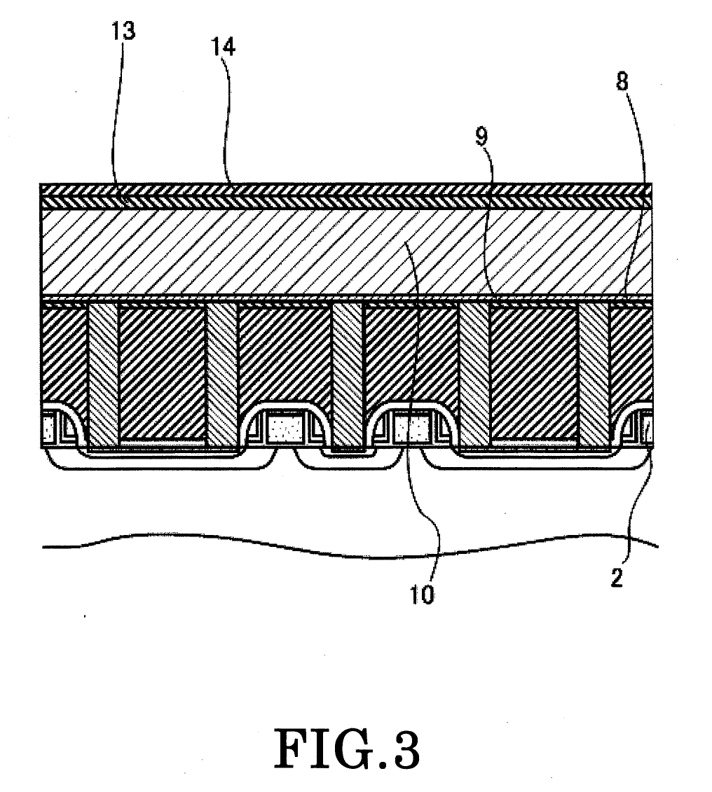

As shown in FIG. 3, the silicon film 9 is formed on the BPSG film 6 and the single-crystalline silicon plug 7 by selective epitaxial growth (SEG) using the single-crystalline silicon plug 7 as a nucleus. The silicon film 9 has the same crystal structure as the single-crystalline silicon plug 7, as being formed by using the single-crystalline silicon plug 7 as the nucleus. Next, a perovskite type single-crystalline metal film as the lower electrode 10 is formed on the silicon film 9 by sputter or the like. Furthermore, a silicon nitride film as a first hard mask 13 is formed on the perovskite-type single-crystalline metal film 10, and subsequently a silicon oxide film as a second hard mask 14 is formed on the first hard mask 14 by, CVD or the like, for example. When Ir is used as the lower electrode 10, Ir may is desirable to be formed by using sputter at over 300° C. for preventing a hillock formation.

In this embodiment, as the lower electrode 10 is formed on the silicon film 9 constituted with the single-crystalline structure, the lower electrode 10 having a single-crystalline structure lattice-matched with the silicon film 9 can be obtained.

Subsequently, a resist film (not shown) is formed on the silicon oxide film (not shown) using coating or the like, for example. The resist film is patterned by photolithography. The second hard mask 14 and the first hard mask 13 are patterned, for example, by RIE or the like using the resist film patterned as a mask. Successively, the perovskite type single-crystalline metal film 10 and the silicon film 9 are anisotropically etched in an order using the patterned second hard mask 14 and the first hard mask 13 as a mask to form the lower electrode 10 having the columnar-type or the bell shape.

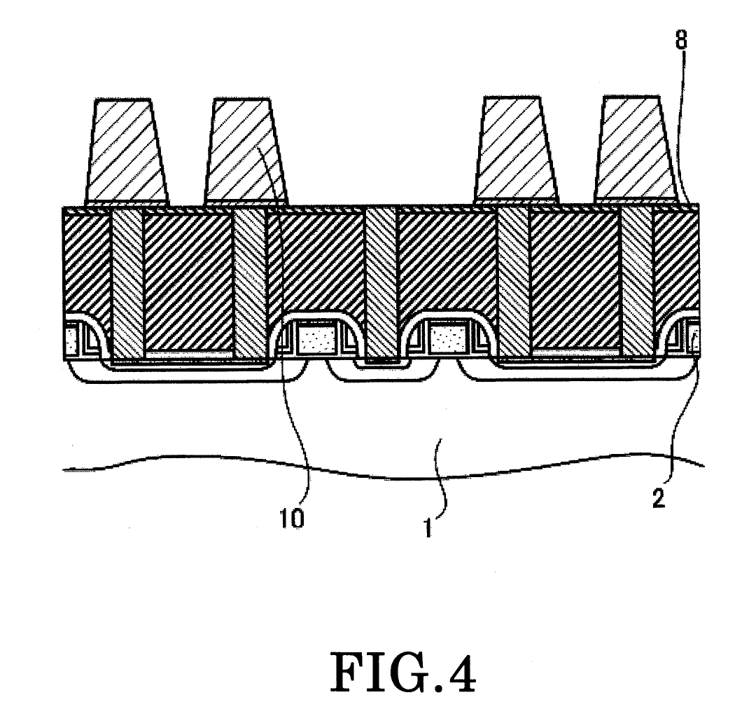

As shown in FIG. 4, after forming the lower electrode 10, the second hard mask 14 and the first hard mask 13 are removed to expose a surface of the lower electrode 10.

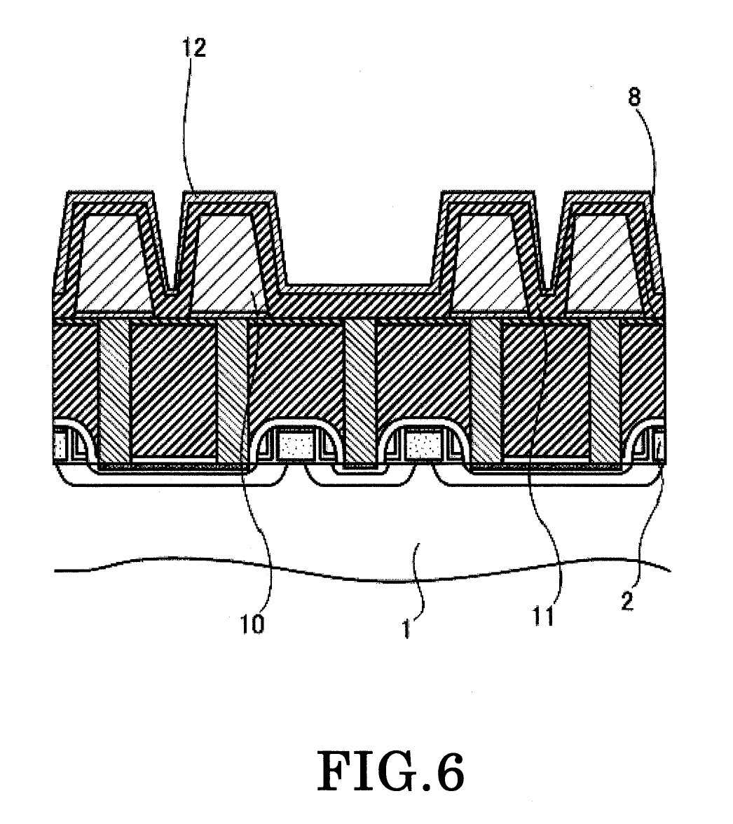

As shown in FIG. 6, the PZT film 11 is formed on the surface of the lower electrode 10 by metal organic chemical vapor deposition (MOCVD). As the PZT film formed by MOCVD has fewer defects therein and at an electrode interface, the PZT film has an excellent reliability on fatigue characteristics, imprint characteristics, retention characteristics or the like as well as superior polarization characteristics. Accordingly, MOCVD may be used as forming the PZT film. Here, as the Al₂O₃ film 8 is formed on the BPSG film 6, reaction between the PZT film 11 and the BPSG film 6 can be suppressed.

Furthermore, as MOCVD provides a good step coverage, a superior controllability of the component, an uniform and high quality film as a large area, a high rate in forming the film, a capability to form thinner ferroelectric film (PZT film) 11 to lower a voltage operation or the like to the electrode structure, MOCVD is desirable to be used as forming the PZT film 11.

As mentioned above, the lower electrode 10 is formed on the silicon film 9 constituted with the single-crystalline structure to lattice-match between the silicon film 9 constituted with the single-crystalline structure and the lower electrode 10 constituted with the single-crystalline structure. Crystallizing a PZT film formed on a sidewall is difficult in a lower electrode having a conventional bell shape. However, the PZT film 11 formed on the sidewall can be lattice-matched to the lower electrode 10 to be crystallized in this embodiment, as the lower electrode is formed as the same the single-crystalline structure as the PZT film 11. As a result, a capacitor having an excellent characteristic can be formed using the PZT film 11 by promoting crystallization of the PZT film 11 having the same crystal structure as the lower electrode 10.

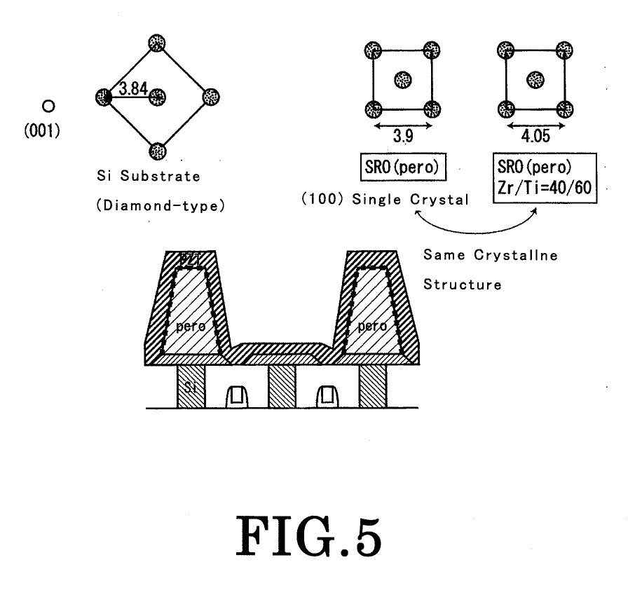

FIG. 5 is a schematic view showing a crystalline structure of each layer in the semiconductor memory device according to the embodiment of the present invention. As shown in FIG. 5, the crystal structure between the perovskite type single-crystalline metal film 10 and the PZT film 11 is approximately the same, therefore, the PZT film 11 can be easily crystallized.

A liquid material is generally used as a source, when the PZT film 11 is formed. For example, tetra hydro furan (THF) is used as a solvent and Pb(dpm)₂/THF, Ti(iPr)₂(dpm)₂/THF or Zr(iPr)₂(dpm)₂/THF is used as the source material, and the PZT film is formed over 600° C. of the forming temperature using oxygen as a reaction gas. After forming, the PZT film 11 is performed to be heat treatment in 400-600° C. as the temperature to crystallize the PZT film 11.

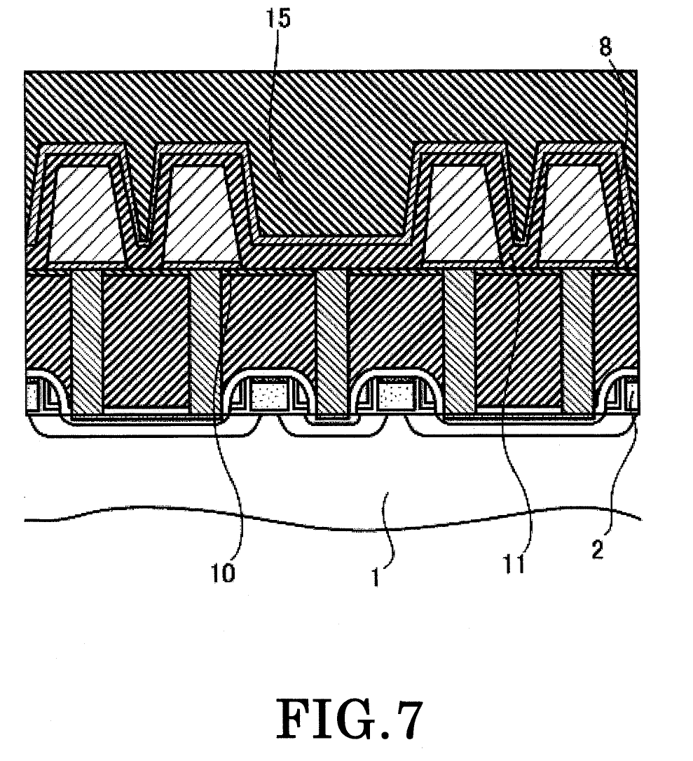

As shown in FIG. 6, the upper electrode 12 constituted with Pt or the like is formed on the PZT film 11. As shown in FIG. 7, after forming the upper electrode 12, an inter layer film 15 is formed on the upper electrode 12. Subsequently, an upper surface of the inter layer film 15 is flattened by CMP.

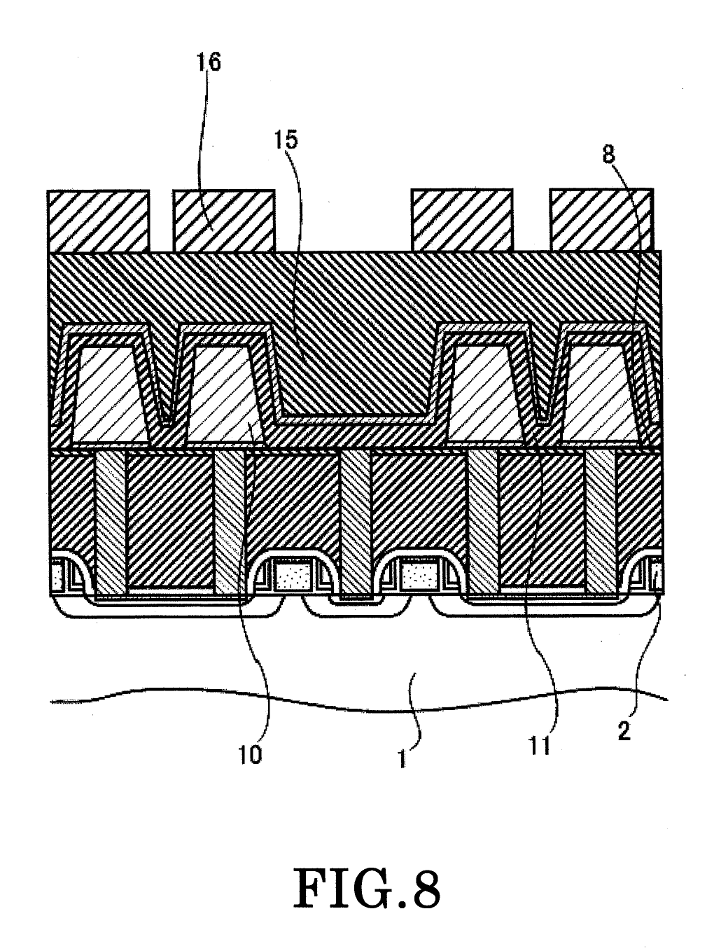

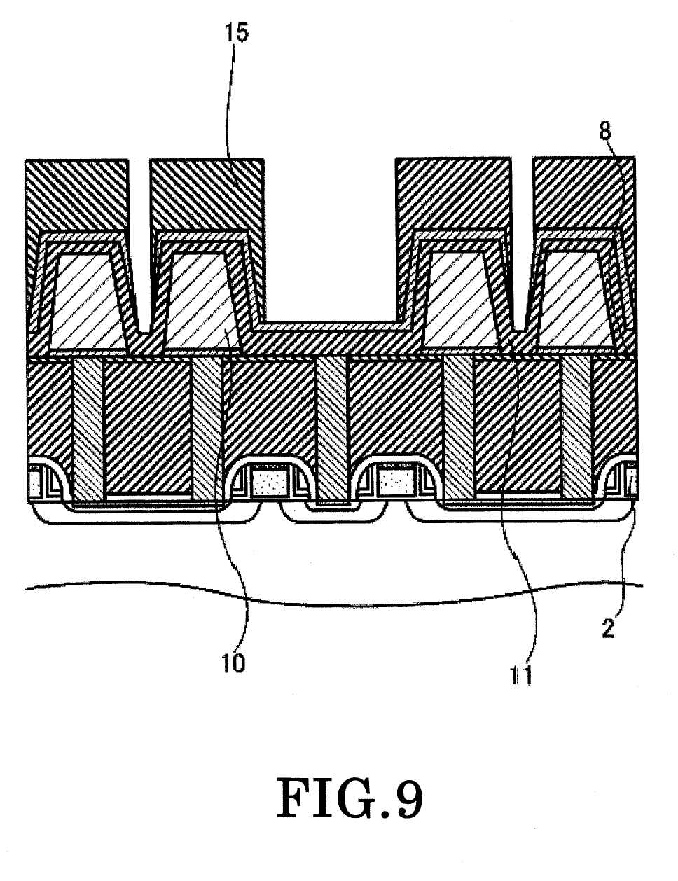

As shown in FIG. 8, a mask material 16 having a prescribed feature and constituted with a resist or a silicon oxide film is formed on the inter layer film 15. A pattern size of the mask material 16 is desirable to be larger than the pattern used in etching the lower electrode 10. As shown in FIG. 9, after forming the mask material 16, the inter layer film 15, the upper electrode 12 and the PZT film 11 is etched by using the mask material 16 as a mask. The ferroelectric may be leaved in a region between the lower electrodes in this process. After etching the PZT film, the mask material is leaved. The ferroelectric capacitor formed in this process has a structure formed through the hydrogen barrier layer 8 constituted with Al₂O₃ or the like in a periphery of a connecting portion with the contact plug 7.

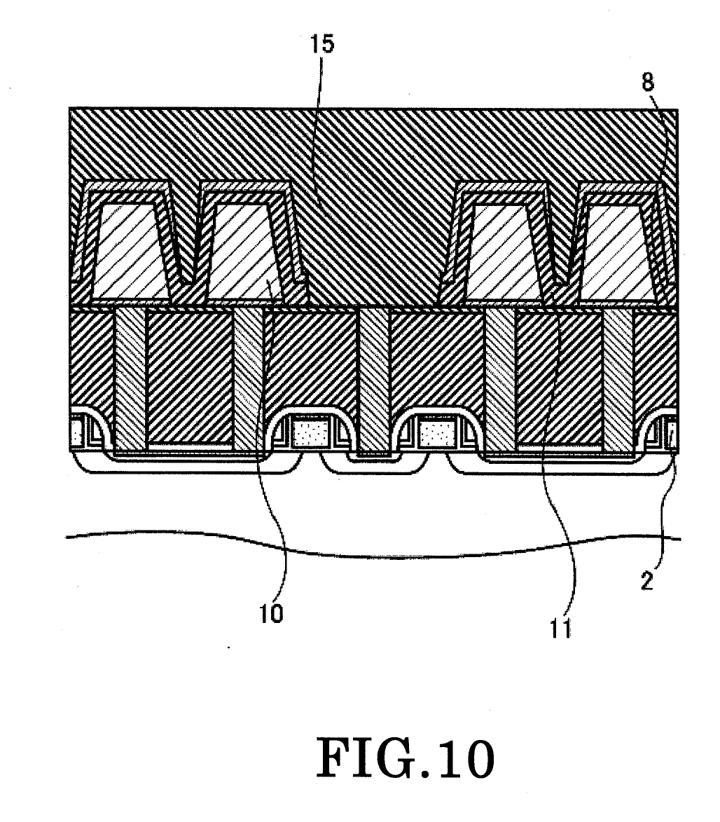

As shown in FIG. 10, after etching the inter layer film 15, the upper electrode 12 and the PZT film 11, the inter layer film 15 constituted with an oxide film or the like is again embedded in, and a surface of the inter layer film 15 in flattened by CMP.

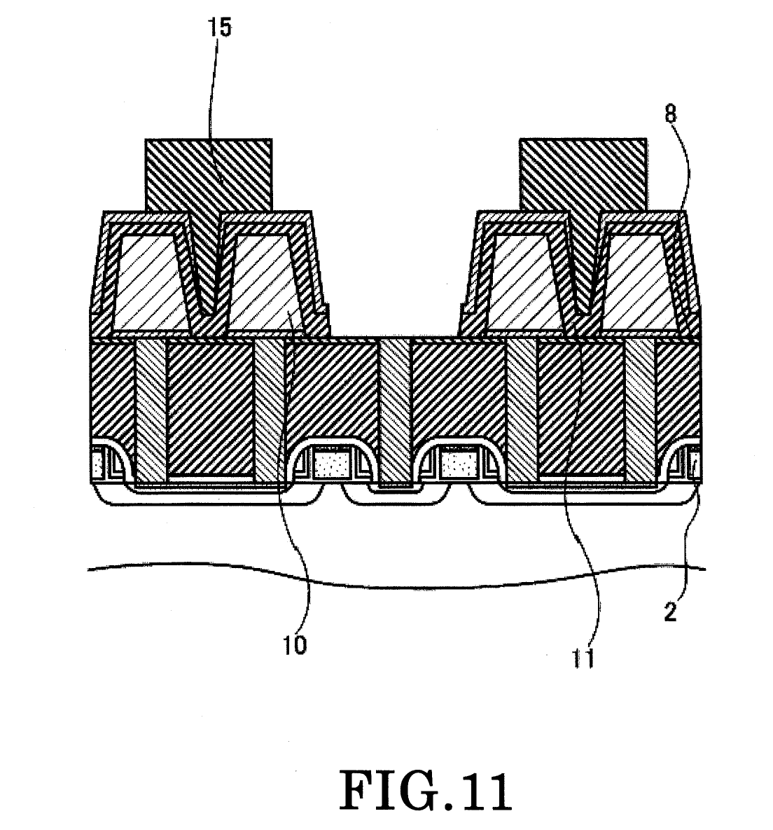

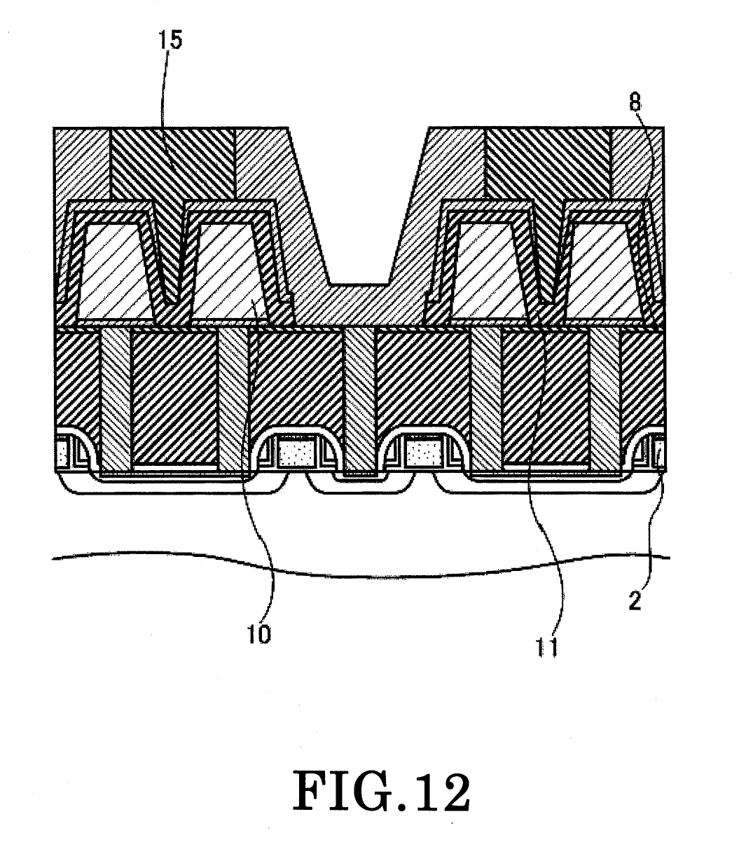

As shown in FIG. 11, patterning for forming wirings is performed, the inter layer film 15 is subsequently etched. In the process, exposing a surface of the single-crystalline silicon plug 7 constituting the wiring is necessary. As shown in FIG. 12, interconnection layer 17 constituted with a metal film, for example, a tungsten film or a copper film is embedded by sputter and an upper surface of the metal film is flattened by CMP. Successively, the inter layer film 15 is again embedded in to complete the structure as shown in FIG. 1.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, this embodiment describes a structure of a Chain-FeRAM. The Chain-FeRAM includes one transistor and one capacitor connected each other in parallel as one cell and a chain structure as an equivalent circuit in which the capacitors are serially connected. Another structure may be used.

What is claimed is:

1. A semiconductor memory device comprising a ferroelectric film, comprising:
a semiconductor substrate;
a field effect transistor on the semiconductor substrate;
an inter-layer insulating film on the field effect transistor and the semiconductor substrate;
a plug comprising a single-crystalline structure in the inter-layer insulating film and connected with a source or a drain of the field effect transistor;
a lower electrode comprising a single-crystalline structure on the plug;
a ferroelectric film on the lower electrode; and
an upper electrode on the ferroelectric film.

2. The semiconductor memory device of claim 1, further comprising:
an underlying layer lattice-matched with the plug between the plug and the lower electrode.

3. The semiconductor memory device of claim 1, wherein
the lower electrode comprises a structure of a columnar type or a bell shape.

4. The semiconductor memory device of claim 1, wherein
the lower electrode is a metal film comprising a perovskite structure lattice-matched with the plug.

5. The semiconductor memory device of claim 4, wherein
the lower electrode comprises a SrRuO₃ single-crystalline film comprising the perovskite structure.

6. The semiconductor memory device of claim 1, wherein
the lower electrode comprises a stack structure comprising a plurality of films.

7. The semiconductor memory device of claim 1, wherein
the plug comprises a single-crystalline silicon film.

8. The semiconductor memory device of claim 1, wherein
the underlying layer comprises the single-crystalline silicon film.

9. The semiconductor memory device of claim 1, wherein
the ferroelectric film is lattice-matched with the lower electrode.

10. The semiconductor memory device of claim 9, wherein
the ferroelectric film is lattice-matched with the lower electrode by thermal annealing.

11. A method for fabricating a semiconductor memory device comprising a ferroelectric film, comprising:
forming a field effect transistor on a semiconductor substrate;
forming an inter-layer insulating film on the field effect transistor and the semiconductor substrate;
forming a plug comprising a single-crystalline structure in the inter-layer insulating film, the plug connected with a source or a drain of the field effect transistor;
forming an lower electrode comprising a single-crystalline structure on the plug;
forming a ferroelectric film on the lower electrode; and
forming an upper electrode on the ferroelectric film.

12. The method of claim 11, further comprising:
forming an underlying layer lattice-matched with the plug, after forming the plug and before forming the lower electrode.

13. The method of claim 11, wherein
the lower electrode is in the shape of a columnar type or a bell.

14. The method of claim 12, wherein
a metal film comprising a perovskite structure is formed as the lower electrode, the metal film being lattice-matched with the plug or the underlying layer.

15. The method of claim 14, wherein
a SrRuO₃ single-crystalline film comprising a metal comprising the perovskite-structure is formed as the lower electrode.

16. The method of claim 11, wherein
a stack structure comprises a plurality of films is formed as the lower electrode.

17. The method of claim 11, wherein
a single-crystalline silicon film is formed as the plug.

18. The method of claim 11, wherein
a single-crystalline silicon film is formed as the underlying layer.

19. The method of claim 11, wherein
the ferroelectric film is formed to be lattice-matched with the lower electrode.

20. The method of claim 11, further comprising:
performing a heat treatment process after forming the ferroelectric film on the lower electrode.
